(19) United States
(12) Patent Application Publication
(10) Pub. No.: US 2016/0324003 A1
(43) Pub. Date: Nov. 3, 2016

(54) PRINTED BOARD FOR MOUNTING MICROCOMPUTER THEREON, AND CONTROL APPARATUS USING SAME

(71) Applicant: SUMITOMO WIRING SYSTEMS, LTD., Yokkaichi-shi, Mie (JP)

(72) Inventor: Tomoya HAYASHI, Yokkaichi, Mie (JP)

(73) Assignee: Sumitomo Wiring Systems, Ltd., Mie (JP)

(21) Appl. No.: 15/104,962

(22) PCT Filed: Nov. 25, 2014
(86) PCT No.: PCT/JP2014/081023

§ 371 Date: Jun. 15, 2016

(30) Foreign Application Priority Data
Dec. 16, 2013 (JP) 2013-258804

(51) Int. Cl. H05K 1/18; H05K 7/14; H05K 1/11

(52) U.S. Cl. CPC H05K 1/181; H05K 1/11; H05K 7/1427; H05K 2201/10545

(57) ABSTRACT

This invention provides a microcomputer mounting printed board that has a novel structure and enables the mounting of microcomputers having different pin arrangements or sizes without designing and manufacturing a new printed board, and a control apparatus that uses this microcomputer mounting printed board. At least a first microcomputer mounting pattern and a second microcomputer mounting pattern are formed on a microcomputer mounting printed board on which a microcomputer is to be mounted. Also, in a control apparatus in which an internal circuit is housed inside a case, the internal circuit is constituted including this microcomputer mounting printed board.

### CROSS-REFERENCE TO RELATED APPLICATIONS

This application is the U.S. national stage of PCT/JP2014/081023 filed Nov. 25, 2014, which claims priority of Japanese Patent Application No. JP2013-258804 filed Dec. 16, 2013.

### FIELD OF THE INVENTION

The present invention relates to a microcomputer mounting printed board on which different microcomputers can be mounted, and a control apparatus that uses this microcomputer mounting printed board.

### BACKGROUND

Conventionally, microcomputers mounted on printed boards have been widely used for performing control of various types of electrical components in automobiles. More specifically, as shown in FIG. 1 of JP H11-39279A (Patent Document 1) for example, in addition to a microcomputer, various types of external components that are essential to operation of the microcomputer, such as a memory, are mounted on a printed board. For each microcomputer that is to be mounted on the printed board, a wiring pattern optimized so as to correspond to the pin arrangement of the microcomputer is provided on the printed board, and predetermined functions can be satisfied by connecting this wiring pattern to the various types of external components.

However, although there have not particularly been any problems in performing control of various types of electrical components of an automobile with use of a control apparatus constituted using a printed board optimized for each microcomputer that is to be mounted thereon as described above, in an unexpected case such as a disaster like the Great East Japan earthquake, obtaining the microcomputer being used becomes difficult for an extended period of time, and this has caused the problem of hindering the manufacturing of printed boards and thus control apparatuses.

In order to address this problem, it is conceivable to substitute a different microcomputer that has the same pin arrangement and size, for example, but it is easily anticipated that it will be difficult to obtain this microcomputer as well due to an increase in demand, and this cannot be said to be a preferable solution. It is also conceivable to substitute a different microcomputer that has a different pin arrangement or size, but this requires the redesign and manufacture of a new printed board, which incurs a vast amount of time, labor, and cost, and therefore this cannot be said to be a preferable solution either.

The present invention was achieved in light of the above-described situation, and a problem to be solved by the present invention is providing a microcomputer mounting printed board that has a novel structure and enables the mounting of microcomputers having different pin arrangements or sizes without designing and manufacturing a new printed board.

Furthermore, another object of the present invention is to provide a novel control apparatus that uses this microcomputer mounting printed board.

### SUMMARY OF INVENTION

In a first aspect of the present invention related to a microcomputer mounting printed board, at least a first microcomputer mounting pattern and a second microcomputer mounting pattern are formed on a printed board on which a microcomputer is to be mounted.

With the microcomputer mounting printed board of this aspect, at least two microcomputer mounting patterns, namely the first microcomputer mounting pattern and the second microcomputer mounting pattern, are formed on the printed board, and at least two types of microcomputers, namely the first microcomputer and the second microcomputer, can be selectively mounted on one type of printed board. In other words, even in the case where one type of microcomputer is in short supply, there is no need to redesign and manufacture a new printed board, and replacing the microcomputer can be performed by merely mounting a different type of microcomputer on the original type of printed board. Accordingly, it is possible to eliminate the needless vast amount of time, labor, and cost that would be incurred in redesigning and manufacturing a new printed board, and to advantageously prevent a short supply situation.

Note that the first microcomputer mounting pattern and the second microcomputer mounting pattern may be formed in different layers of the printed board, or may be formed in the same layer. For example, the first microcomputer mounting pattern and the second microcomputer mounting pattern may be formed at different places in the same layer of the printed board, and if one of the patterns is sufficiently smaller than the other one, both of the patterns can be formed in the same region by providing the larger pattern in the peripheral portion and providing the smaller pattern in the central portion. Also, if space allows, it is possible to further improve versatility by further forming a third microcomputer mounting pattern or even more microcomputer mounting patterns.

A second aspect of the present invention related to a microcomputer mounting printed board is the microcomputer mounting printed board according to the first aspect, wherein the first microcomputer mounting pattern is formed on one of upper or lower surfaces of the printed board, and the second microcomputer mounting pattern is formed on the other surface of the printed board.

According to this aspect, the first microcomputer mounting pattern is formed on the upper surface of the printed board, and the second microcomputer mounting pattern is formed on the lower surface of the printed board, for example. In other words, the first microcomputer mounting pattern and the second microcomputer mounting pattern are formed on different surfaces of the printed board, and therefore the pattern can have a simpler and more compact design compared to the case where the patterns are provided on the same surface. Furthermore, it is possible to advantageously ensure identifiability for the microcomputer mounting patterns in the assembly step.

A third aspect of the present invention related to a microcomputer mounting printed board is the microcomputer mounting printed board according to the first or second aspect, wherein the second microcomputer mounting pattern includes a conduction path that connects a mounting region for a second microcomputer to a wiring pattern of the first microcomputer mounting pattern.

According to this aspect, the second microcomputer mounting pattern is constituted by the conduction path that connects the mounting region for the second microcomputer to the wiring pattern of the first microcomputer mounting pattern. Specifically, by using the wiring pattern of the first microcomputer mounting pattern as the wiring pattern for mounting various types of external components that are essential to operation of the microcomputer, such as a memory, the pattern can have an even simpler and more compact design. In other words, the second microcomputer mounting pattern is formed so as to simply correct a difference in pin arrangement from the first microcomputer mounting pattern.

In a first aspect of the present invention related to a control apparatus, in a control apparatus in which an internal circuit is housed inside a case, the internal circuit is constituted including the microcomputer mounting printed board according to any one of the first to third aspects.

According to this aspect, in the control apparatus in which the internal circuit is housed inside the case, the internal circuit is constituted including the microcomputer mounting printed board of the present invention. Accordingly, even in an unexpected case such as a disaster like the Great East Japan earthquake, the microcomputer being used in the control apparatus can be easily replaced, thus making it possible to advantageously prevent a situation in which the control apparatus is in short supply.

According to the present invention, at least two microcomputer mounting patterns, namely a first microcomputer mounting pattern and a second microcomputer mounting pattern, are formed on a printed board, and therefore even in the case where one type of microcomputer is in short supply, there is no need to redesign and manufacture a new printed board, and microcomputer replacement can be performed by merely mounting a different type of microcomputer on the original type of printed board. Accordingly, it is possible to eliminate the needless vast amount of time, labor, and cost that would be incurred in the case of redesigning and manufacturing a new printed board, and to advantageously prevent a short supply situation.

### BRIEF DESCRIPTION OF DRAWINGS

FIG. 1 is a perspective diagram showing a state during assembly of an electrical connection box configured including a control apparatus that houses a microcomputer mounting printed board serving as a first embodiment of the present invention.

FIG. 2 is a plan view at the time of assembly of the electrical connection box shown in FIG. 1.

FIG. 3 is an exploded perspective view of the control apparatus shown in FIG. 1.

FIG. 4 is a perspective view of the microcomputer mounting printed board shown in FIG. 3 ((a) being the case where the microcomputer and the like are mounted on a first microcomputer mounting pattern formed on the upper surface of the printed board, and (b) being the case where the microcomputer and the like are mounted on a second microcomputer mounting pattern formed on the lower surface of the printed board).

FIG. 5 is an enlarged view of a main part of a microcomputer mounting printed board serving as a second embodiment of the present invention ((a) being a plan view, and (b) being a bottom view).

### DETAILED DESCRIPTION OF THE PREFERRED EMBODIMENTS

Hereinafter, embodiments of the present invention will be described with reference to the drawings.

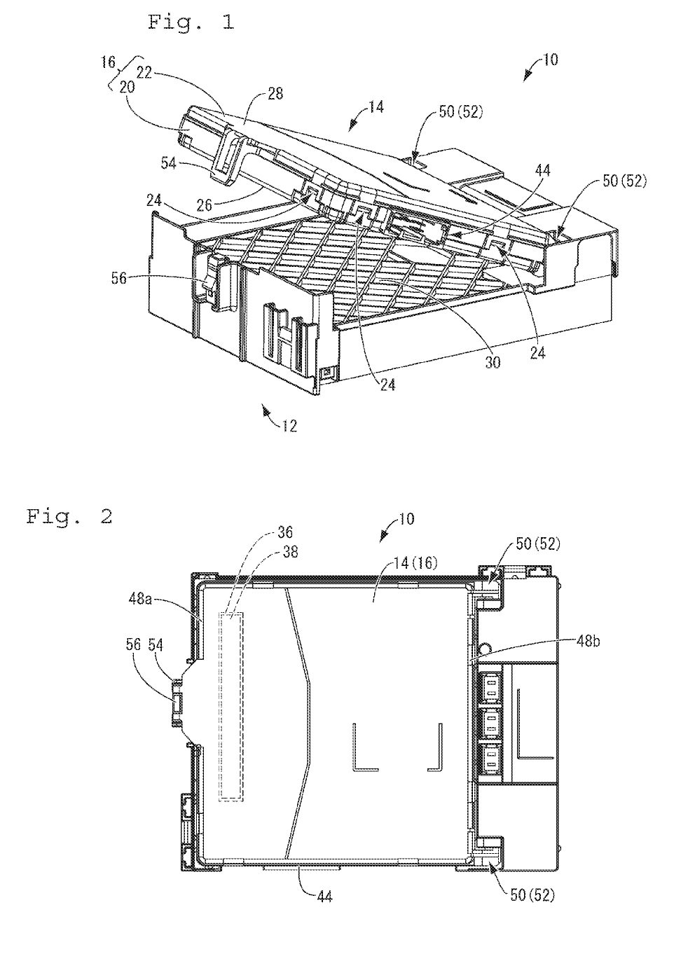

Firstly, an electrical connection box 10 is shown in FIGS. 1 and 2. The electrical connection box 10 includes a main body 12 and a control apparatus 14, according to the present invention, that is separate from the main body 12. The control apparatus 14 is a vehicle electronic control unit such as an ECU and, due to being attached and electrically connected to the main body 12, the control apparatus 14 receives a supply of power from the main body 12 and performs control of electrical components, such as relays (not shown), that are mounted in the main body 12. Note that the electrical connection box 10 of the present invention is a junction block, a fuse box, a relay box, or the like.

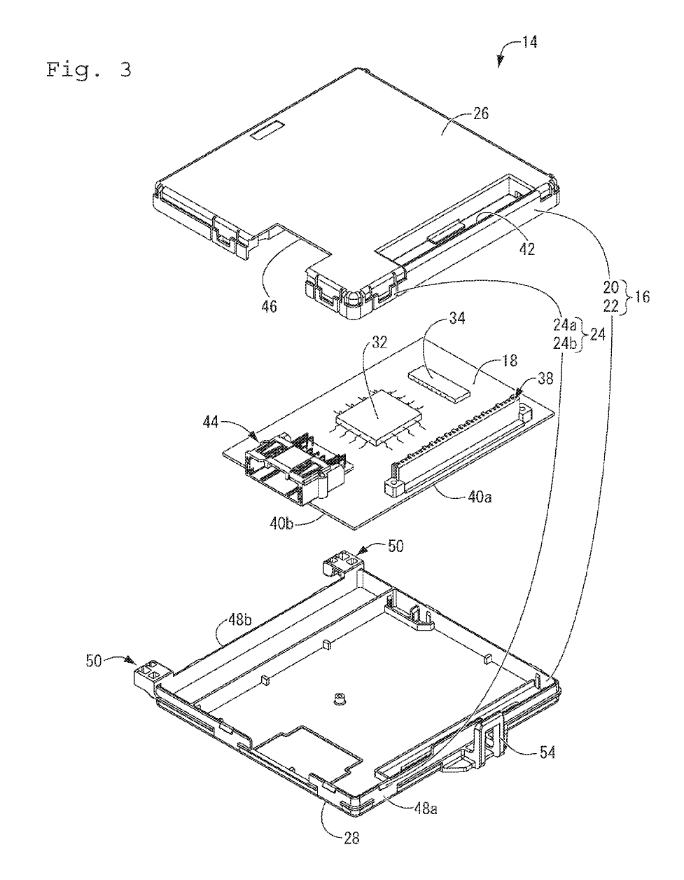

As shown in FIG. 3, the control apparatus 14 has a structure in which a microcomputer mounting printed board 18, which is the internal circuit serving as a first embodiment of the present invention, is housed inside a case 16 formed from synthetic resin. The case 16 has a hollow box structure in which an upper case 20 and a lower case 22, which are shaped as approximately rectangular boxes that are open on one side, are overlaid in a state in which their open portions are covered by one another, and are fixed to each other in a locked manner by lock portions 24 that are each constituted by a lock arm 24a and a lock 24b. An upper surface 26 and a lower surface 28 of the case 16 have a rectangular shape and are slightly smaller than an attachment surface 30 (see FIG. 1) of the main body 12, and the upper surface 26 of the case 16 is the surface that is overlaid on the attachment surface 30 in the state where the case 16 is attached to the main body 12 of the control apparatus 14. Note that in the following description, the upward direction refers to the upward direction in FIG. 3, and the downward direction refers to the downward direction in FIG. 3.

As shown in FIG. 3, the microcomputer mounting printed board 18 housed in the case 16 is shaped as a rectangular plate, and a microcomputer 32 as well as various types of external components that are essential to operation of the microcomputer 32, such as a memory 34, are mounted as necessary in the central portion of the microcomputer mounting printed board 18. Also, a control apparatus-side connector 38, which is for connection to a main body-side connector 36 (see FIG. 2) provided on a printed board (not shown) of the main body 12, and a later-described side connection connector 44 are additionally mounted on the microcomputer mounting printed board 18. The control apparatus-side connector 38, the later-described side connection connector 44, and the various types of external components such as the memory 34 are electrically connected to the microcomputer 32 by a wiring pattern (not shown) provided on the microcomputer mounting printed board 18. Note that the control apparatus-side connector 38 extends along one side edge portion 40a of the microcomputer mounting printed board 18, and when the microcomputer mounting printed board 18 is housed inside the case 16, the control apparatus-side connector 38 protrudes upward from the upper surface 26 of the case 16 via an opening hole 42 provided in the upper case 20. On the other hand, the side connection connector 44 extends along a side edge portion 40b that is orthogonal to the one side edge portion 40a of the microcomputer mounting printed board 18. When the microcomputer mounting printed board 18 is housed inside the case 16, the side connection connector 44 protrudes from a side surface of the case 16 via a cutout portion 46 formed in the upper case 20, and a connector (not shown) is connected to this side connection connector 44.

As shown in FIGS. 1 to 3, a pair of rotation portions 50, which are shaped as approximately rectangular blocks and protrude outward, are respectively provided on the two end portions of a side edge portion 48b (on the right side in FIG. 2) of the case 16 on the side opposite to the side edge portion 48a where the control apparatus-side connector 38 protrudes.

The main body 12 and the control apparatus 14 having the above-described structures are assembled using a known technique such as that disclosed in JP 2010-200503A, for example. Specifically, first, as shown in FIG. 1, the rotation portions 50 are inserted into support portions 52, 52 of the main body 12, with the upper surface 26 of the control apparatus 14 opposing the attachment surface 30 of the main body 12. Hinges are thus formed by the rotation portions 50 and the support portions 52. Next, the control apparatus 14 is overlaid on the attachment surface 30 of the main body 12 by rotating the control apparatus 14 about the rotation portions 50, 50. As a result, the control apparatus-side connector 38 provided on the control apparatus 14 is inserted into the main body-side 36 that protrudes from the attachment surface 30 of the main body 12, and the microcomputer mounting printed board 18 of the control apparatus 14 is electrically connected to the printed board (not shown) of the main body 12. A lock arm 54 provided on the side edge portion 48a side of the control apparatus 14, which is opposite to the rotation portions 50, and a lock 56 provided on the main body 12 engage with each other, thus fixing the control apparatus 14 to the main body 12 and completing the assembly.

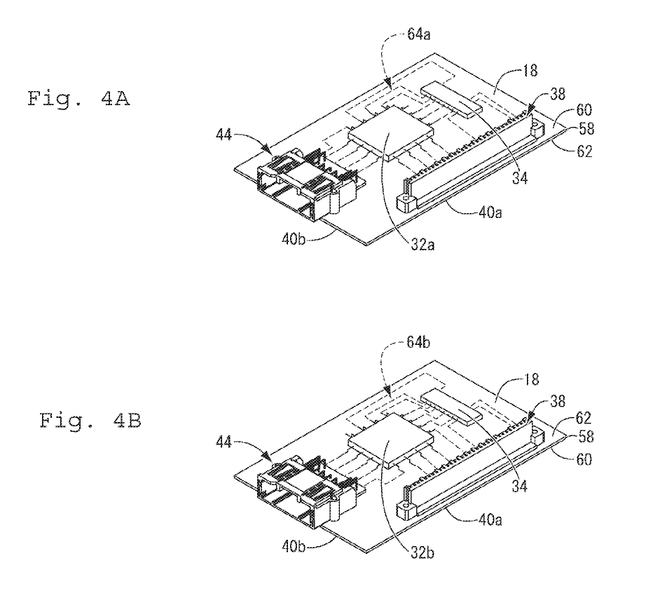

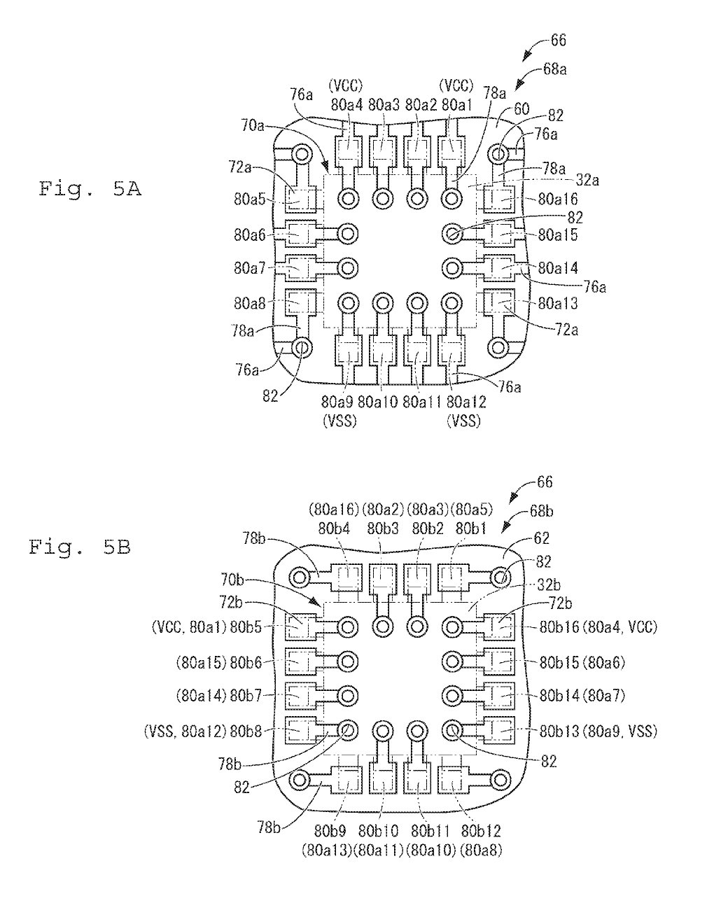

Next, a method of using the microcomputer mounting printed board 18 serving as the first embodiment of the present invention will be described in detail using FIG. 4. As shown in FIG. 4, the microcomputer mounting printed board 18 is constituted including an insulated substrate 58 that is shaped as an approximately rectangular flat plate and is formed by a known insulating material such as glass epoxy resin, and a first microcomputer mounting pattern 64a and a second microcomputer mounting pattern 64b respectively provided on an upper surface 60 and a lower surface 62 of the insulated substrate 58. Specifically, a first microcomputer 32a and a second microcomputer 32b that have different pin arrangements can be mounted on the upper surface 60 and the lower surface 62 of the microcomputer mounting printed board 18, and therefore mounting patterns 64a and 64b optimized so as to accommodate each of the pin arrangements are provided. Accordingly, as shown in FIG. 4(a), the first microcomputer 32a as well as the control apparatus-side connector 38, the side connection connector 44, and various types of external components such as the memory 34 can be mounted to the first microcomputer mounting pattern 64a provided on the upper surface 60 of the microcomputer mounting printed board 18, whereas as shown in FIG. 4(b), the second microcomputer 32b as well as the control apparatus-side connector 38, the side connection connector 44, and various types of external components such as the memory 34 can be mounted to the second microcomputer mounting pattern 64b provided on the lower surface 62 of the microcomputer mounting printed board 18. Accordingly, in normal use, the first microcomputer 32a, which is the main microcomputer, as well as the connectors 38 and 44 and the various types of external components are mounted to the first microcomputer mounting pattern 64a provided on the upper surface 60, whereas in the case where the first microcomputer 32a is in short supply during a disaster or the like, the second microcomputer 32b, which is a backup microcomputer, as well as the connectors 38 and 44 and the various types of external components can be mounted to the second microcomputer mounting pattern 64b provided on the lower surface 62.

In this way, the second microcomputer mounting pattern 64b that enables mounting the second microcomputer 32b, which is a backup microcomputer, is provided on the lower surface 62 of the microcomputer mounting printed board 18 in advance, thus making it possible to easily replace the microcomputer 32 without redesigning and manufacturing a new microcomputer mounting printed board. Accordingly, it is possible to eliminate the needless vast amount of time, labor, and cost that would be incurred in the case of redesigning and manufacturing a new microcomputer mounting printed board, and to advantageously prevent a short supply situation.

Also, in the present embodiment, the first microcomputer mounting pattern 64a and the second microcomputer mounting pattern 64b are formed on different surfaces, namely the upper and lower surfaces, of the microcomputer mounting printed board 18, and therefore the mounting pattern can have a simpler and more compact design compared to the case where the mounting patterns are provided on the same upper surface 60, for example. Additionally, in the step for mounting the microcomputer and the like, the microcomputer mounting patterns 64a and 64b can be easily identified due to the surfaces for mounting the microcomputers 32a and 32b being different from each other, and therefore it is possible to advantageously prevent the microcomputers 32a and 32b from being mounted on the wrong microcomputer mounting patterns.

Next, a microcomputer mounting printed board 66 serving as a second embodiment of the present invention will be described in detail using FIG. 5, and members and portions having a structure similar to that in the above embodiment will be denoted in the figures by the same reference signs as in the above embodiment, and thus detail descriptions will not be given for them. Specifically, this microcomputer mounting printed board 66 is an embodiment different from the above embodiment in that a second microcomputer mounting pattern 68b is constituted including conduction paths 78b for connecting a mounting region 70b and pad portions 72b for the second microcomputer 32b to a wiring pattern 76a of a first microcomputer mounting pattern 68a.

As shown in FIG. 5(a), the first microcomputer mounting pattern 68a provided on the upper surface 60 of the microcomputer mounting printed board 66 is constituted including a mounting region 70a for the first microcomputer 32a, pad portions 72a, conduction paths 78a for connecting terminals 80a1-80a16 for the first microcomputer 32a to corresponding terminals 80b1-80b16 for the second microcomputer 32b on the lower surface 62 via through-holes 82, and the wiring pattern 76a for connecting various types of external components and the various types of connectors 38 and 44 to the terminals 80a1-80a16 for the first microcomputer 32a. In other words, the pattern formed on the upper surface 60 of the microcomputer mounting printed board 66 is similar to the first microcomputer mounting pattern 64a that is provided on the upper surface 60 of the microcomputer mounting printed board 18 of the previous embodiment.

On the other hand, as shown in FIG. 5(b), the second microcomputer mounting pattern 68b provided on the lower surface 62 of the microcomputer mounting printed board 66 is constituted including the mounting region 70b for the second microcomputer 32b, the pad portions 72b, and the conduction paths 78b for connecting the terminals 80b1-80b16 for the second microcomputer 32b to the corresponding terminals 80a1-80a16 for the first microcomputer 32a on the upper surface 60 via the through-holes 82. Note that the corresponding terminals referred to above are terminals that have the same functions, and specifically they refer to the terminals with terminal numbers (80a1-80a16) that are indicated in parentheses next to the terminals 80b1-16 in FIG. 5(b). Here, the terminals 80b5 and 80b16 are VCC terminals connected to a power supply, and the terminals 80b8 and 80b13 are VSS terminals connected to ground.

In other words, in the present embodiment, the second microcomputer mounting pattern 68b only connects the terminals 80b1-16 for the second microcomputer 32b to the corresponding terminals 80a1-16 for the first microcomputer 32a, and the wiring pattern 76a of the first microcomputer mounting pattern 68a provided on the upper surface 60 of the microcomputer mounting printed board 66 serves as the wiring pattern for connection to the various types of external components and the various connectors 38 and 44 and the connection thereof to the terminals 80b1-80b16 for the second microcomputer 32b. For this reason, it is possible to give the second microcomputer mounting pattern 68b a simpler and more compact design.

Although embodiments of the present invention have been described above, the present invention is not limited in any way by the specific descriptions in these embodiments. Although both the first microcomputer mounting pattern 64a, 68a and the second microcomputer mounting pattern 64b, 68b are formed on different surfaces of the microcomputer mounting printed board 18, 66 in the embodiments, the first microcomputer mounting pattern and the second microcomputer mounting pattern may be formed at different places on the same surface of the microcomputer mounting printed board. Furthermore, if one of the microcomputer mounting patterns is sufficiently smaller than the other one, both of the microcomputer mounting patterns can be formed in the same region by providing the larger pattern in the peripheral portion and providing the smaller pattern in the central portion. Also, if space allows, it is possible to further improve versatility by further forming a third microcomputer mounting pattern or even more microcomputer mounting patterns using one surface or both the upper and lower surfaces of the microcomputer mounting printed board.

1. A microcomputer mounting printed board comprising:
at least a first microcomputer mounting pattern and a second microcomputer mounting pattern being formed on a printed board on which a microcomputer is to be mounted.

2. The microcomputer mounting printed board according to claim 1,
further including an upper surface opposite a lower surface, wherein the first microcomputer mounting pattern is formed on one of either the upper surface or the lower surface of the printed board, and
the second microcomputer mounting pattern is formed on the other of the upper surface or lower surface of the printed board.

3. The microcomputer mounting printed board according to claim 1, wherein the second microcomputer mounting pattern includes a conduction path that connects a mounting region for a second microcomputer to a wiring pattern of the first microcomputer mounting pattern.

4. A control apparatus in which an internal circuit is housed inside a case, wherein the internal circuit is constituted including the microcomputer mounting printed board according to claim 1.

5. The microcomputer mounting printed board according to claim 2, wherein the second microcomputer mounting pattern includes a conduction path that connects a mounting region for a second microcomputer to a wiring pattern of the first microcomputer mounting pattern.

6. A control apparatus in which an internal circuit is housed inside a case, wherein the internal circuit is constituted including the microcomputer mounting printed board according to claim 2.

7. A control apparatus in which an internal circuit is housed inside a case, wherein the internal circuit is constituted including the microcomputer mounting printed board according to claim 3.
